(19) United States
(12) Patent Application Publication
(10) Pub. No.: US 2011/0215684 A1
(43) Pub. Date: Sep. 8, 2011

(54) APPARATUS WITH CASE

(75) Inventors: YUN-LUNG CHEN, Tu-Cheng (TW); CHANG-YONG HU, Shenzhen City (CN); WEI-YONG MA, Shenzhen City (CN)

(73) Assignees: HONG FU JIN PRECISION INDUSTRY (ShenZhen) CO., LTD., ShenZhen City (CN); HON HAI PRECISION INDUSTRY CO., LTD., Tu-Cheng (TW)

(21) Appl. No.: 12/889,548

(22) Filed: Sep. 24, 2010

(30) Foreign Application Priority Data
Mar. 2, 2010 (CN) 201010116175.0

(51) Int. Cl. H05K 5/02

(52) U.S. Cl. 312/223.1

(57) ABSTRACT

An apparatus includes a case. The case includes a wall. A wall flange is located on the wall. The wall flange includes a base plate and a supporting portion located on the base plate. A plurality of pairs of cutouts are defined in the supporting portion. An extending tab is located between each pair of cutouts. A distance defined between the extending tab and the base plate.

### CROSS-REFERENCE TO RELATED APPLICATIONS

This application is related to co-pending application entitled, “APPARATUS WITH CASE”, filed on _, application Ser. No. ______, (Atty. Docket No. US32740).

### BACKGROUND

1. Technical Field

The present disclosure relates to an apparatus with a case, which has improved electronic magnetic interference (EMI)-resistant capability.

2. Description of Related Art

EMI exists in many electronic devices, such as computer systems. Therefore, an electronic device enclosure should be designed to reduce EMI from harming users or interference with other electronic device, so there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an apparatus in accordance with an embodiment.

FIG. 2 is an enlarged view of portion II of the apparatus of FIG. 1.

FIG. 3 is similar to FIG. 1, and shows a cover secured to a case.

FIG. 4 is a cross-section view of the apparatus of FIG. 3 along a direction IV-IV.

FIG. 5 is an isometric view of an apparatus of a related art.

FIG. 6 is an enlarged view of portion VI of the apparatus of FIG. 5.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

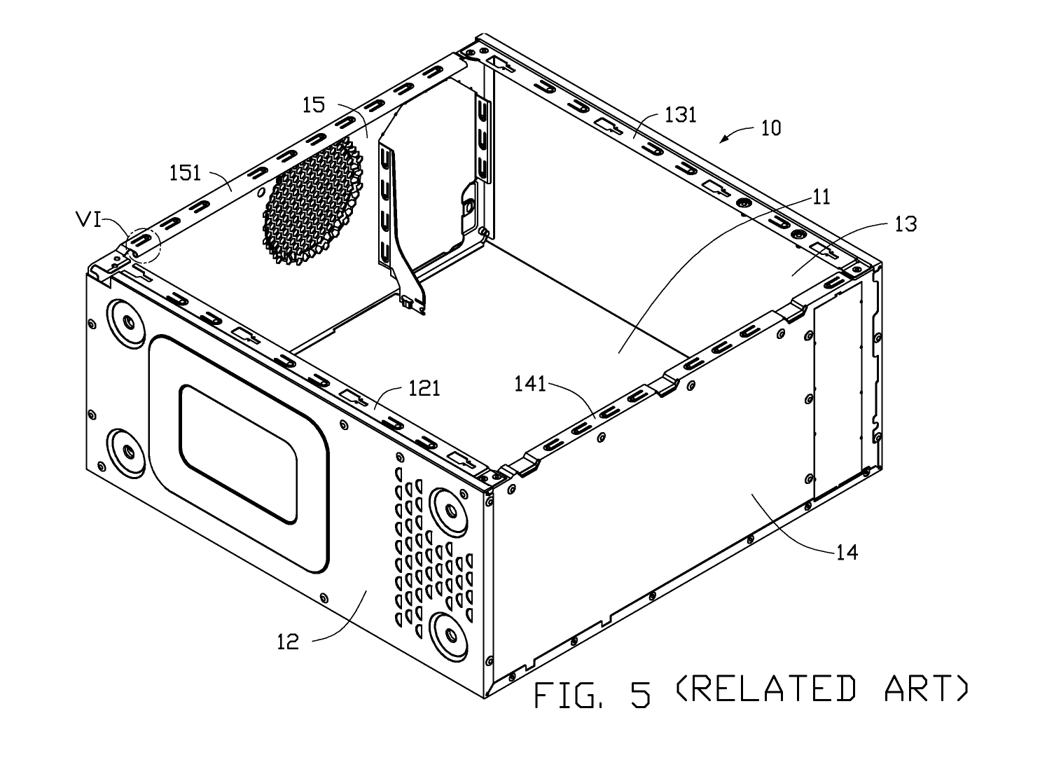

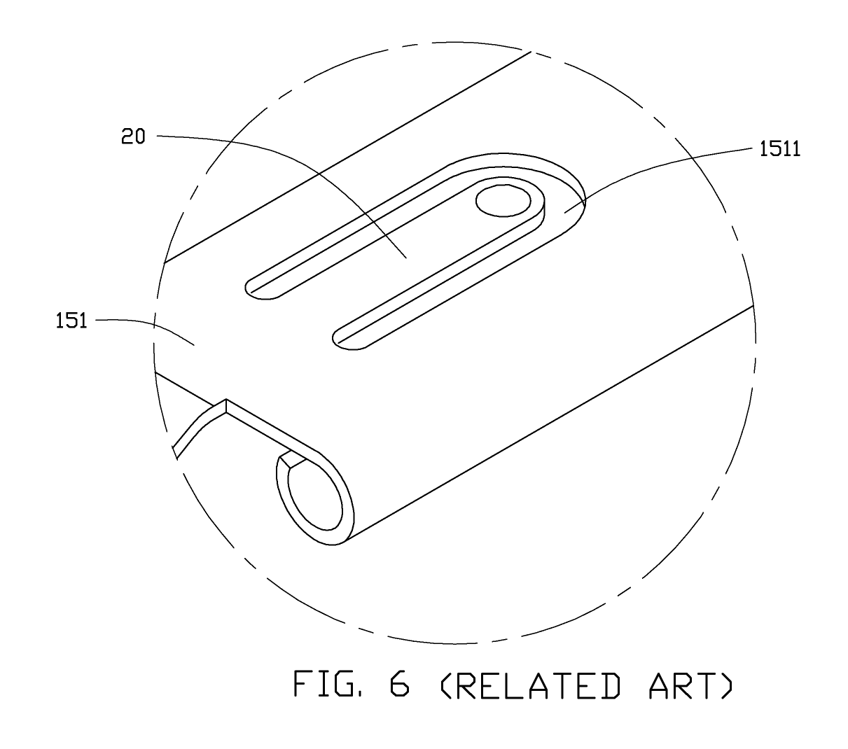

Referring to FIGS. 5-6, a conventional apparatus includes a chassis 10. The chassis 10 includes a side plate 11, a bottom plate 12, a top plate 13, a front plate 14 and a rear plate 15. The side plate 11, the bottom plate 12, the top plate 13, the front plate 14, and the rear plate 15 are perpendicularly located on the side plate 11. The bottom plate 12 is parallel to the top plate 13. The front plate 14 is parallel to the rear plate 15, and perpendicular to the bottom and top plates 12, 13. A supporting flange 151 is located on a top edge of the rear plate 15. A plurality of through holes 1511 is defined in the supporting flange 151. A finger piece 20 extends in each through holes 1511 in a direction parallel to the rear plate 15 and perpendicular to the bottom and top plates 12, 13. The finger pieces 20 can contact electrically with a cover (not shown), which is secured to the side plate 11, the bottom plate 12, the top plate 13, the front plate 14, and the rear plate 15 to cover the chassis 10, for reducing EMI from harming users or interference with other electronic devices. However, the finger pieces 20 when pressed to deform continually, such as when removing and installing the cover repeatedly, can decrease EMI resistance capability.

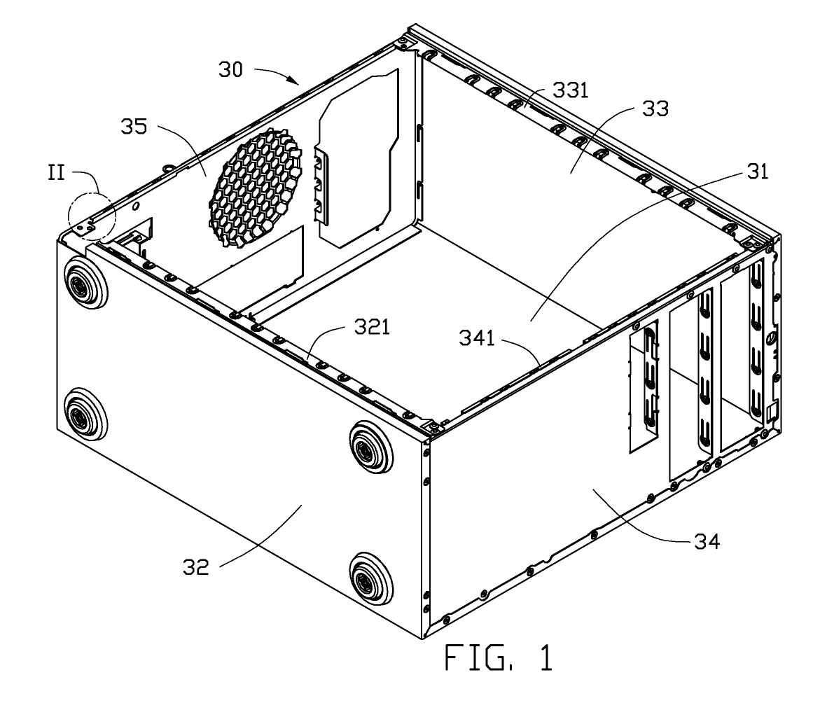

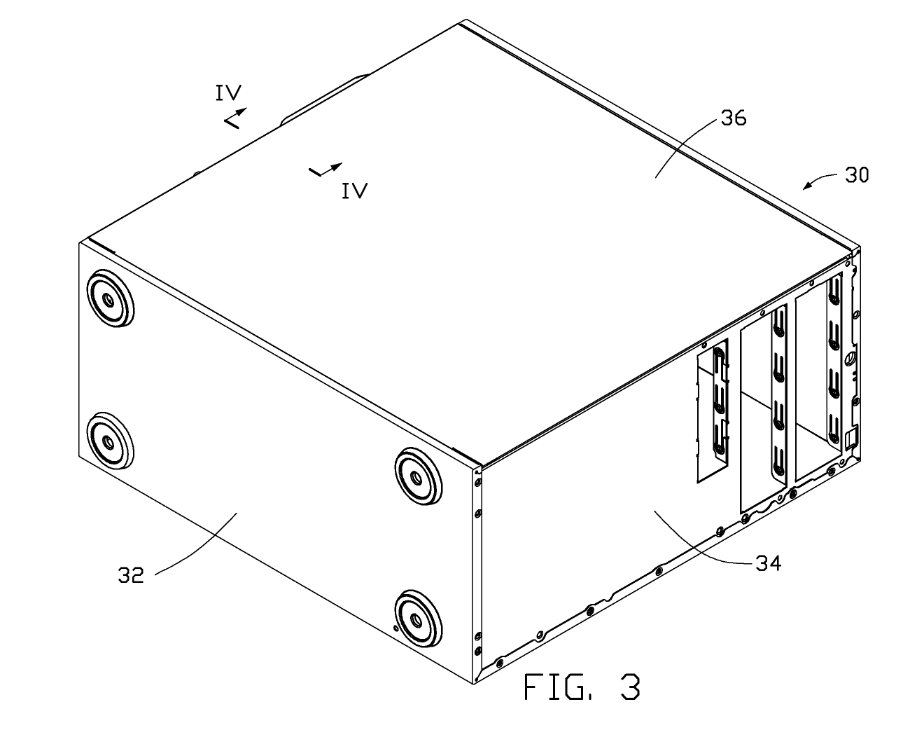

An improved apparatus is provided. Referring to FIG. 1, the apparatus in accordance with an embodiment includes a case 30. The case 30 includes a sidewall 31, a bottom wall 32, a top wall 33, a front wall 34, a rear wall 35, and a cover 36 (shown in FIG. 3). The top wall 33, the front wall 34, and the rear wall 35 are located on the sidewall 31. The bottom and top walls 32, 33 are positioned between the front and rear walls 34, 35. In one embodiment, the top wall 33, the front wall 34, and the rear wall are substantially perpendicular to the sidewall 31, the bottom wall 32 is substantially parallel to the top wall 33 and perpendicular to the front and rear wall 34, 35, and the front wall 34 is substantially parallel to the rear wall 35.

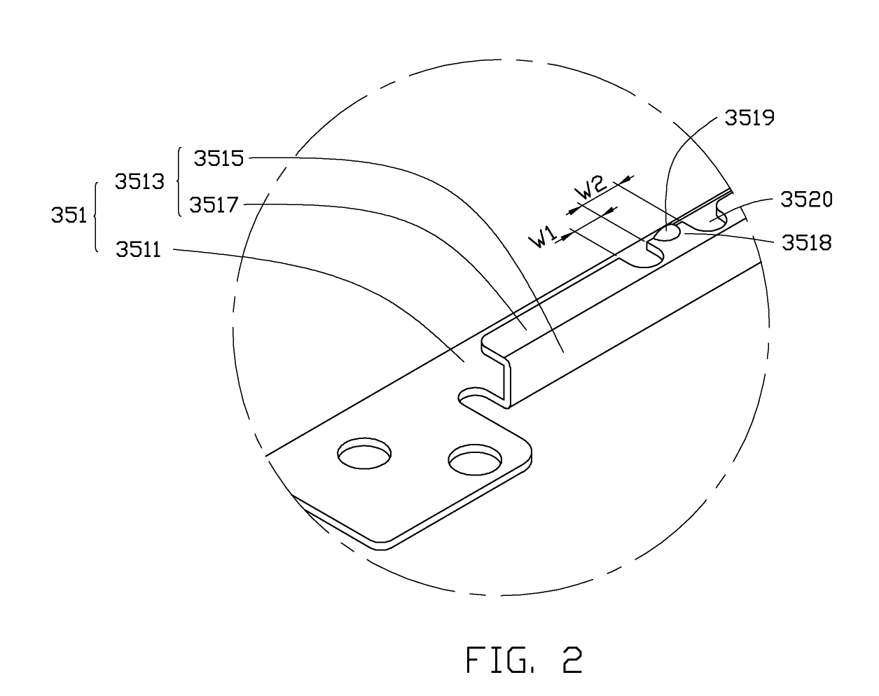

A first wall flange 321 is located on a top edge of the bottom wall 32. A second wall flange 331 is located on a top wall 33. A third wall flange 341 is located on a top edge of front wall 34. A fourth wall flange 351 (shown in FIG. 2) is located on a top edge of the rear wall 35. The third wall flange 341 is secured to the first and second wall flange 321, 331. One end of the fourth wall flange 351 is secured to the second wall flange 331.

Referring to FIGS. 1-2, the fourth flange 351 includes a base plate 3511 and a supporting portion 3513. The base plate 3511 extends from the rear wall 35. The supporting portion 3513 is located on the base plate 3511. The supporting portion 3513 includes a connecting plate 3515 located on the base plate 3511 and a supporting plate 3517 located on the connecting plate 3515. In one embodiment, the base plate 3511 and the supporting plate 3517 are substantially perpendicular to the rear wall 35, and the connecting plate 3515 is substantially parallel to the rear wall 35.

A plurality of pairs of cutouts 3520 are defined in the supporting plate 3517, along a direction substantially perpendicular to the rear wall 35. An extending tab 3518 with a protrusion 3519 is located on the supporting plate 3517 between each pair of cutouts 3520 and extends in a direction substantially perpendicular to the rear wall 35.

In one embodiment, each cutout 3520 has a first width W1, and each extending tab 3518 has a second width W2. The width W1 is not less than 2 mm and not greater than 3.5 mm and the width W2 is not less than 3 mm and not greater than 4 mm. In another embodiment, the width W1 is 2.5 mm, and the width W2 is 3.2 mm.

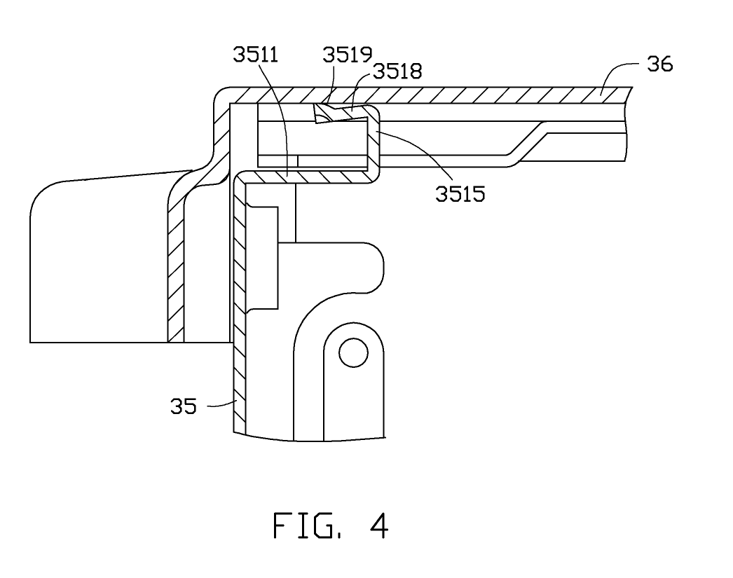

Referring to FIGS. 3-4, in use, the cover 36 is secured to the case 30. The first through third wall flanges 32, 33 and 34 contact with the cover 36, and the supporting plate 3517 and the protrusions 3519 of the extending tabs 3518 contact with the cover 36, for reducing EMI from harming users. The extending tabs 3518 are resiliently deformed.

Because the fourth wall flange 351 includes the base plate 3511 and the supporting portion 3513, so the fourth wall flange 351 can be reinforced. Therefore, the fourth flange 351 can be made of a relatively thin gauge metal, such as a 0.4 mm, and still be strong enough to secure the cover 36 of the case 30. Furthermore, the cutouts 3520 extend in a direction substantially perpendicular to the rear wall 35 and have sufficient enough width, so a die, that has the same size as the width W1 of the cutouts 3520 and is used to punch the cutouts 3520, can be strong enough not to be easily damaged in the punching process. In addition, the extending tabs 3518 also have sufficient enough width, so as to be reinforced to improve EMI-resistant capability.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A apparatus comprising:
a case, the case comprising a wall, a wall flange located on the wall, the wall flange comprising a base plate and a supporting portion located on the base plate, a plurality of pairs of cutouts defined in the supporting portion, an extending tab located between each pair of cutouts, a distance defined between the extending tab and the base plate.

2. The apparatus of claim 1, wherein a width of each cutout is not less than 2 mm, but not greater than 3.5 mm.

3. The apparatus of claim 2, wherein the width of each cutout is 2.5 mm.

4. The apparatus of claim 1, wherein a width of each extending tab is not less than 3 mm, but not greater than 4 mm.

5. The apparatus of claim 4, wherein the width of each extending tab is about 3.2 mm.

6. The apparatus of claim 1, wherein the base plate is substantially perpendicular to the wall.

7. The apparatus of claim 6, wherein the supporting portion comprises a connecting plate and a supporting plate; the connecting plate is substantially parallel to the wall and perpendicular to the base plate; the supporting plate is substantially perpendicular to the connecting plate; and the extending tabs and the plurality of pair of cutouts are located on the horizontal portion.

8. The apparatus of claim 1, further comprising a cover secured to the wall, the extending tabs contacting with the cover.

9. A apparatus comprising:
a case, the case comprising a wall, a wall flange located on the wall, the wall flange comprising a base plate and a supporting portion located on the base plate; the supporting portion comprising a connecting plate and a supporting plate; the connecting plate connected between the base plate and the supporting plate; a plurality of extending tabs extending from the supporting plate in a direction substantially perpendicular to the wall, for contacting with a cover.

10. The apparatus of claim 9, wherein a plurality of pair of cutouts is defined in the supporting plate; and each extending tab is located between each pair of cutouts.

11. The apparatus of claim 10, wherein a width of each cutout is not less than 2 mm, but not greater than 3.5 mm.

12. The apparatus of claim 11, wherein the width of each cutout is about 2.5 mm.

13. The apparatus of claim 9, wherein a width of each extending tab is not less than 3 mm, but not greater than 4 mm.

14. The apparatus of claim 12, wherein the width of each extending tab is about 3.2 mm.

15. The apparatus of claim 9, wherein the base plate is substantially perpendicular to the wall; and the supporting plate is substantially perpendicular to the base plate.

16. The apparatus of claim 15, wherein the connecting plate is substantially perpendicular to the supporting plate and the base plate.
